(19) United States
(12) Patent Application Publication
(10) Pub. No.: US 2026/0068351 A1
(43) Pub. Date: Mar. 5, 2026

(54) METHOD FOR TREATING A PHOTOSENSOR, SYSTEM FOR TREATING A PHOTOSENSOR, AND OPTICAL MEASURING SYSTEM COMPRISING SUCH A SYSTEM

(71) Applicant: Carl Zeiss SMT GmbH, Oberkochen (DE)

(72) Inventors: Lutz Brekerbohm, Jena (DE); Daniel Weller, Oberkochen (DE)

(21) Appl. No.: 19/312,630

(22) Filed: Aug. 28, 2025

(30) Foreign Application Priority Data
Sep. 2, 2024 (DE) 102024125005.4

(51) Int. Cl. H10F 71/00; G03F 7/00

(52) U.S. Cl. CPC H10F 71/134; G03F 7/70516; G03F 7/706

(57) ABSTRACT

A method for treating a photosensor, in particular for use in an optical measuring system for semiconductor lithography. The photosensor has a sensor surface having a plurality of photosensitive pixels which are designed to convert light into an electrical signal using the internal photoelectric effect. The method comprises the following steps:
determining an extent of an image aberration caused by a dark current effect and/or a ghosting effect;
irradiating the sensor surface of the photosensor with UV light; and
repeating the determination of the extent of the image aberration and the irradiation of the sensor surface until the determined extent of the image aberration falls below a specified level.

The quality of the photosensor is improved by the UV irradiation.

### CROSS-REFERENCE TO RELATED APPLICATION

The present application claims the priority of the German patent application DE 10 2024 125 005.4, filed on Sep. 2, 2024, the entire contents of which are incorporated herein by reference.

### TECHNICAL FIELD

The invention relates to a method for treating a photosensor, in particular for use in an optical measuring system for semiconductor lithography, and to a system for treating a photosensor, and to an optical measuring system comprising such a system for treating a photosensor.

### BACKGROUND

Semiconductor lithography is used for producing microstructured components, such as integrated circuits. The microlithography process is carried out in what is known as a projection exposure apparatus, which has an illumination system and a projection system. The image of a mask (also called “reticle”) illuminated by use of the illumination system is projected in this case with the aid of the projection system onto a substrate, for example a silicon wafer, that is coated with a light-sensitive layer (so-called “photoresist”) and is arranged in the image plane of the projection system, in order to transfer the mask structure to the coated substrate. In subsequent production steps, the transferred structure is implemented in the substrate, e.g., by etching or material deposition.

To ensure a high quality of the imaging generated on the coated substrate, it is necessary for the mask to be true to size and not adversely affected by contaminations. It is known practice to subject photomasks to an inspection, either prior to operation in a microlithographic projection exposure apparatus or during an interruption of operation. To this end, a so-called aerial image of the mask or of a portion of the mask is generated, the photomask in the process being imaged onto a photosensor, rather than onto the coated substrate. Using the imaging onto the photosensor as a basis, it is possible to assess whether the photomask is without defects and contaminations.

Photosensors based on the internal photoelectric effect, in particular CCD sensors (charge-coupled device sensors) and CMOS sensors (complementary metal oxide semiconductor sensors), are also used, inter alia, in digital photo and video cameras as well as in medical, industrial and scientific applications in which high-quality image data and in particular very high light sensitivity are required. For the above-mentioned application in semiconductor lithography, in particular the measurement of masks for EUV lithography, photosensors of particularly high quality are needed to measure the structures of the mask with the required accuracy.

### SUMMARY

An aspect of the present invention is to provide a method for treating a photosensor, a system for treating a photosensor, and an optical measuring system, with which the quality of a photosensor can be improved. This aspect is achieved by the features of the independent claims. Advantageous embodiments are specified in the dependent claims.

Accordingly, the invention relates to a method for treating a photosensor which may be designed in particular for use in an optical measuring system for semiconductor lithography. The photosensor has a plurality of photosensitive pixels which are designed to convert light into an electrical signal using the internal photoelectric effect. The method comprises the following steps:
determining an extent of an image aberration caused by a dark current effect and/or a ghosting effect;
irradiating a sensor surface of the photosensor with UV light;
repeating the determination of the extent of the image aberration and the irradiation of a sensor surface until the determined extent of the image aberration falls below a specified level.

The “dark current effect” and the “ghosting effect” are generally known effects in the field of photosensors that can lead to incorrect detection of image signals (cf. “Rest et al. (2002), Residual images in charged-coupled device detectors, Review of Scientific Instruments, Vol. 73, 2028-2032”). In the context of the present description, the “dark current effect” refers to the problem of one or more pixels producing a faulty electrical signal which is not due to light being incident on the respective pixel, but in particular also occurs in absolute darkness. When performing a light measurement, the dark current effect increases an intensity of the measured light signal, thus distorting it.

In the context of the present description, the “ghosting effect” refers to the problem, when two different images are captured in succession, of the first image being superimposed on the second image with lower intensity. This results in a distortion of the second image. Both effects can occur with both CCD sensors and CMOS sensors.

Within the scope of the invention, it was recognized that the quality of the photosensor can be improved by the irradiation of the sensor surface with UV light by virtue of the dark current effect and/or the ghosting effect occurring only to a lesser extent after the UV irradiation. It is assumed that an electronic state density within the sensor material responsible for the photoelectric effect and/or within adjacent material layers is changed by the irradiation with UV light, which leads to the occurrence of at least one of the two effects being reduced.

By repeating the determination of the extent of the image aberration, it can be determined whether the irradiation with UV light was already sufficient to reduce the image aberrations to a desired level. The specified measure, after which further irradiation with UV light is no longer necessary, may have a specification for the occurrence of the dark current effect and/or a specification for the occurrence of the ghosting effect. For example, a specification for the occurrence of the dark current effect or the ghosting effect may include a specification for a maximum electrical signal that may be generated by a pixel despite darkness. The specification for the occurrence of the ghosting effect may be a specification of a maximum electrical signal for a pixel that was illuminated in a first image captured by the photosensor and was not illuminated in a second image captured by the photosensor shortly thereafter.

It is possible for an irradiation parameter used for the irradiation to be selected on the basis of the extent of the dark current effect and/or the ghosting effect. The at least one irradiation parameter may be selected in particular from the group comprising irradiation duration, irradiation intensity and irradiation wavelength. A wavelength of the UV light used during irradiation can be between 150 nm and 350 nm, in particular between 200 nm and 300 nm. By adapting the irradiation with UV light, it is possible to accurately improve the quality of the photosensor.

The extent of the image aberration can be determined by determining a dark current effect of the photosensor. In particular, provision may be made for electrical signals generated by the photosensor to be captured while the photosensor is in complete darkness. It is also possible in principle for the photosensor to be illuminated by a known or calibrated light distribution, wherein a light distribution detected by the sensor is compared with the calibrated light distribution in order to determine the dark current effect. The captured electrical signals may include information about which pixels generate dark current, the amount of dark current generated by each of those pixels and/or a sum of electrical signals generated by those pixels.

In one embodiment, the determination of the extent of the image aberration comprises the following steps:
successively detecting a first light distribution and a second light distribution different from the first by use of the photosensor;
determining an effect of detecting the first light distribution on an image obtained by detecting the second light distribution.

By detecting two different light distributions in two successive measurements, it can be determined whether the photosensor, when detecting the second light distribution, indicates a light intensity at those points which were illuminated by the first light distribution and were not illuminated by the second light distribution. A time interval between the successive detection of the two light distributions can be in a range between 100 ms and 100 s, in particular between 200 ms and 50 s. The second light distribution can be detected by capturing an image in darkness (i.e. in a light distribution which is “zero” across the entire sensor).

The sensor surface can be irradiated in such a way that a difference between radiation intensities that are incident on different sections of the sensor surface is less than 10% of a maximum radiation intensity, in particular less than 5% of a maximum radiation intensity. It has been shown that, with homogeneous irradiation, the quality of the photosensor can be improved uniformly and over the entire sensor surface.

In one embodiment, a UV light source is used to determine the extent of the image aberration, wherein the irradiation is also carried out with the aid of the UV light source. This has the advantage that only one light source is needed to carry out the method. Alternatively, provision may be made for a first light source to be used to determine the extent of the image aberration, wherein the sensor surface is irradiated with UV light with the aid of a second light source different from the first. In this case, the second light source may be specially adapted to perform the irradiation with UV light, while the first light source may be optimized to detect the image aberration.

In one embodiment, the method is carried out within a mask inspection apparatus. The mask inspection apparatus may include an illumination source and an illumination optical unit for illuminating an object plane. A mask to be examined can be positioned in the object plane in order to be inspected. The mask inspection apparatus may also have a projection optical unit for imaging the object plane onto the photosensor. Provision may be made for the illumination source or a UV light source different from the illumination source to be used to irradiate the sensor surface via the illumination optical unit, a mirror surface positioned in the object plane and the projection optical unit. Alternatively, it is also possible for the sensor surface to be irradiated starting from the UV light source via an optical path separate from the illumination optical unit and the projection optical unit. The illumination source may be designed to emit EUV light or DUV light.

In one embodiment, provision is made for the mask inspection apparatus to be used for a certain period of time and/or for a certain number of mask inspection operations after carrying out the method for treating the photosensor. Provision may also be made for the method for treating the photosensor to be carried out after using the mask inspection apparatus over a certain period of time and/or for a number of mask inspection operations. In this way, the photosensor can be regularly checked and treated, so that the quality of the photosensor is always ensured.

In one embodiment, the photosensor is a CCD sensor. Alternatively, the photosensor may also be a CMOS sensor, in particular an active pixel sensor or a passive pixel sensor.

It is possible for the method for treating a first photosensor to be carried out in order to determine at least one irradiation parameter, with which the extent of the image aberration is reduced below the specified level, wherein the at least one irradiation parameter is used to irradiate a sensor surface of a second photosensor different from the first photosensor. The second photosensor may be in particular of the same design or from the same production batch as the first photosensor. The at least one irradiation parameter may be selected from the group comprising irradiation duration, irradiation intensity and irradiation wavelength.

The invention further relates to a system for treating a photosensor, in particular for use in an optical measuring system for semiconductor lithography, wherein the photosensor has a sensor surface having a plurality of photosensitive pixels which are designed to convert light into an electrical signal using the internal photoelectric effect, comprising: a holder for the photosensor; a UV light source for illuminating a sensor surface of the photosensor held by the holder; an evaluation unit which is designed to receive sensor data from the photosensor and to determine an extent of an image aberration of the photosensor that is caused by a dark current effect and/or by a ghosting effect; a control unit which is configured to interact with the evaluation unit and the UV light source in such a way that the method according to one of claims 1 to 12 is carried out.

The system for treating a photosensor can be developed by further features which have already been described above in connection with the method according to the invention.

The invention further relates to an optical measuring system for measuring an optical property of an object, in particular for measuring a quality of a lithographic mask, wherein the object can be arranged in an object plane of the optical measuring system. The optical measuring system comprises an illumination source; a photosensor having a sensor surface having a plurality of photosensitive pixels which are designed to convert light into an electrical signal using the internal photoelectric effect; an illumination optical unit which is designed to transform light from the illumination source into an illumination beam path for illuminating the object plane; a projection optical unit for imaging the object plane onto the sensor surface; a UV light source for irradiating the sensor surface with UV light; an evaluation unit which is designed to receive sensor data from the photosensor and to determine an extent of an image aberration of the photosensor that is caused by a dark current effect and/or by a ghosting effect; and a control unit which is configured to receive information about the extent of the image aberration from the evaluation unit and to deliver control signals to the UV light source, as well as to adapt the control signals on the basis of the information about the extent of the image aberration.

The optical measuring system can be developed by further features which have already been described above in connection with the method according to the invention. In particular, the optical measuring system can be an EUV mask inspection apparatus. Furthermore, the illumination source may be an EUV illumination source. The illumination optical unit and the projection optical unit may each have optical elements which are designed to reflect EUV radiation, such as mirrors having multilayer coatings that reflect EUV light. The lithographic mask to be measured can be a lithographic mask that reflects EUV radiation.

In one embodiment, the optical measuring system is configured to image either light from the UV light source or light from the EUV illumination source onto the photosensor via the illumination optical unit and the projection optical unit. For example, it may be possible to switch off the EUV illumination source or block out its light, wherein the optical measuring system may have a displacement device for displacing the UV light source such that the light from the UV light source reaches the object plane via the illumination optical unit, possibly with the aid of additional optical elements. The optical measuring system may have a mirror surface which can be alternatively moved into the object plane instead of the mask, with the result that the UV light illuminating the object plane is directed via the mirror surface to the projection optical unit and is imaged by the latter onto the sensor surface.

### BRIEF DESCRIPTION OF DRAWINGS

Embodiments of the invention are explained by way of example below with reference to the accompanying drawings, in which:

FIG. 1: shows a schematic illustration of a system according to the invention for treating a photosensor;

FIG. 2: shows a schematic illustration of a mask inspection apparatus according to the invention;

FIG. 3: shows a schematic illustration of a further embodiment of a mask inspection apparatus according to the invention;

FIG. 4: shows a schematic illustration of the embodiment from FIG. 3 in a different state.

### DETAILED DESCRIPTION

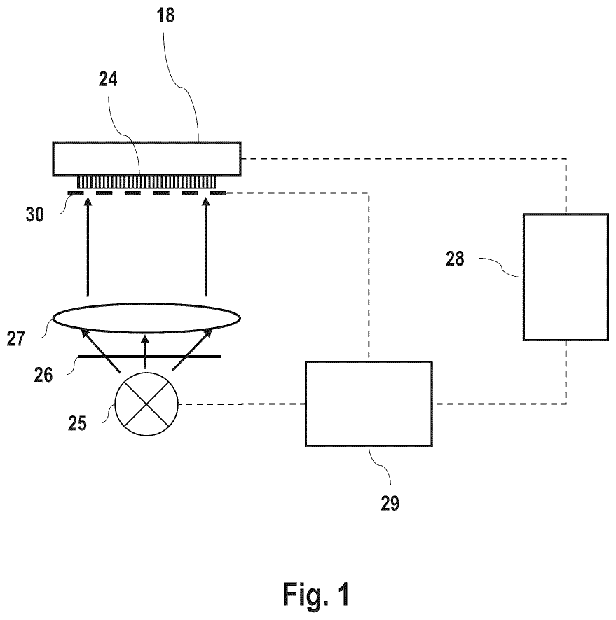

FIG. 1 shows an example of a system according to one or more aspects of the invention for treating a photosensor 24. The photosensor 24 is in the form of a CCD sensor and is held by a holder 18. The system comprises a UV light source 25, the light from which is directed via a homogenizer 26 and an optional collimator 27 to the photosensor 24 in order to irradiate it with UV light. The photosensor 24 comprises a plurality of pixels which together form a sensor surface. When a light beam of sufficient intensity is incident on one of the pixels, the photoelectric effect generates an electrical signal associated with the pixel. The electrical signal is then read out in a generally known manner and forwarded as a measuring signal to an evaluation unit 28. An image can be assembled in this way from the electrical signals generated by the plurality of pixels. The system further comprises a variable stop device 30 (or variable aperture device) which is positioned between the collimator 27 and the photosensor 24 for the purpose of generating a specific illumination pattern. The variable stop device 30 can include at least one moving element configured to partially or fully block the beam path. The variable stop device 30 is connected to the control unit 29 and can be controlled by the latter. For example, the variable stop device 30 can be switched to a state in which it blocks out a part of the beam path, with the result that only a part of the sensor surface is illuminated. It is also possible for the stop device 30 to block out the entire beam path.

To carry out the method, the entire beam path is initially blocked out with the aid of the variable stop device 30, with the result that no light is incident on the photosensor 24. At the same time, an electrical signal generated by the photosensor 24 is read out and forwarded to the evaluation unit 28. In this way, the evaluation unit 28 can determine an extent of an image aberration caused by the dark current effect (hereinafter also referred to as “dark current image aberration”). Since no light is incident on the sensor surface, all detected electrical signals can be assigned to the dark current effect. Determining an extent of the image aberration caused by the dark current effect may include determining which pixels generate dark current electrical signals, determining an amount of electrical signals generated by each of those pixels and/or determining a sum of electrical signals generated by those pixels.

Information about the extent of the dark current image aberration is then forwarded from the evaluation unit 28 to the control unit 29. The control unit 29 determines, on the basis of the received information, irradiation parameters which in particular comprise in the present case an irradiation duration and an irradiation intensity for irradiation with UV light. The control unit 29 then gives an instruction to the variable stop device 30 to allow the beam path to pass unhindered, and controls the UV light source 25 such that UV light, which corresponds to the determined irradiation parameters, is incident on the sensor surface over the entire surface and with high homogeneity. The wavelength of the UV light is 180 nm in the present case. The UV light source 25 can be designed to generate narrowband UV light with the desired wavelength. Alternatively, the UV light source may be designed to generate a UV light spectrum and may have a bandpass filter that is transmissive to UV light of the desired wavelength. The quality of the photosensor is improved by the irradiation with UV light.

The process described above for determining the extent of the dark current image aberration is then repeated in order to determine whether the image aberration has already been reduced to an acceptable level. If this is the case, the method can be ended. The photosensor 24 can then be removed from the system and used, for example, in an optical measuring system, in particular in a mask inspection apparatus, and can be used there to measure EUV masks.

If the extent of the image aberration has not yet fallen below an acceptable level, the process described above can be repeated until the acceptable level is undershot.

As an alternative or in addition to the method explained above, in which the photosensor 24 is treated on the basis of the determined extent of the dark current image aberration, the extent of an image aberration caused by the ghosting effect (hereinafter also referred to as “ghosting image aberration”) can also be determined and used to determine irradiation parameters of the UV irradiation. For this purpose, the UV light source is operated and two different configurations of the stop device 30 are each set in succession and two corresponding images are each captured with the aid of the photosensor 24 and forwarded to the evaluation unit 28. The second image can be captured, in particular, when the stop device 30 is fully closed, with the result that no light is incident on the photosensor during capture of the second image. If, during capture of the second image, electrical signals are nevertheless generated at those pixels which were previously illuminated when capturing the first image, the generation of these electrical signals can be associated with the ghosting effect. It is possible to subtract a possibly previously determined proportion of the electrical signals that can be associated with the dark current effect when determining the ghosting effect. In this way, the evaluation unit 28 determines an extent of the ghosting image aberration and forwards corresponding information to the control unit. This uses the information to determine irradiation parameters for controlling the UV light source 25 in order to improve the quality of the photosensor 24 in the manner already described above.

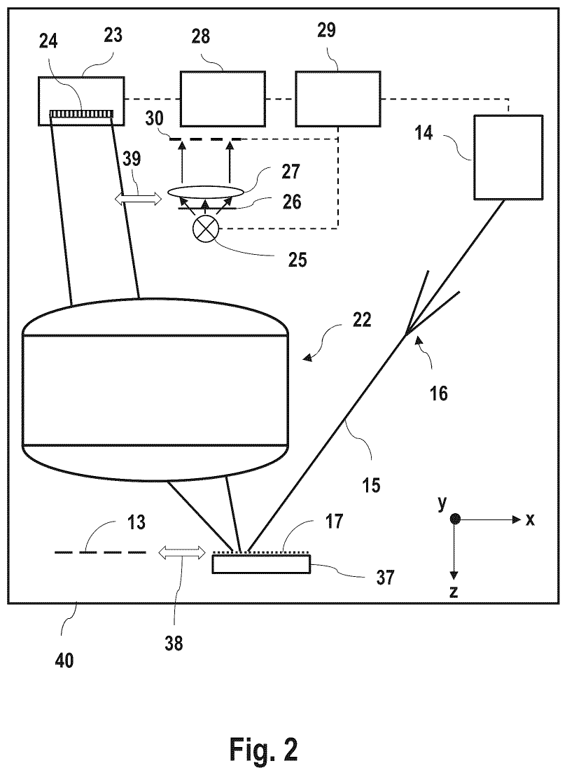

FIG. 2 shows a schematic illustration of an optical measuring system according to the invention. In the present case, the optical measuring system is an EUV mask inspection apparatus that can be used to examine microlithographic photomasks 17. In general, microlithographic photomasks 17 are intended to be used in a microlithographic projection exposure apparatus (not illustrated). In the microlithographic projection exposure apparatus, the photomask 17 is illuminated with extreme ultraviolet radiation (EUV radiation) at a wavelength of for example 13.5 nm in order to image a structure formed on the photomask 17 onto the surface of a coated substrate (for example a silicon wafer). The substrate is coated with a photoresist that reacts to the EUV radiation. The optical measuring system is used to examine whether the measuring device meets the specifications and is free from contaminations.

In the optical measuring system shown in FIG. 2, the photomask 17 is arranged such that an EUV beam path 15 emanating from an EUV radiation source 14 is guided via an illumination system 16 to the photomask 17. The illumination system 16 is used to shape the EUV radiation to form a beam used to illuminate, with uniform brightness, a partial field of the photomask 17 that is in an object plane. The illuminated partial field can have dimensions of 0.5 mm×0.8 mm, for example. The edge lengths of the photomask 17 can be between 100 mm and 200 mm, for example. Using an XY-positioning mechanism 37, it is possible to move the photomask in the XY-plane in order to bring different partial fields of the photomask 17 into the region of the EUV beam path.

The EUV beam path 15 reflected at the photomask 17 continues through a projection lens 22 to a photosensor 24 positioned within an EUV camera 23. The projection lens 22 is used to image the partial field of the photomask 17 onto the photosensor 24 of the EUV camera 23. The EUV radiation source 14, the illumination system 16, the photomask 17, the projection lens 22 and the EUV camera 23 are arranged in a vacuum housing 40, in which a negative pressure prevails during operation of the measuring device.

For example, the EUV radiation source 14 is a plasma radiation source, in which the EUV radiation is emitted from a plasma at a wavelength of 13.5 nm. Tin is a medium that can be used to generate a plasma suitable for emitting such EUV radiation. A laser beam can be made to impinge on a droplet of the medium for the purpose of generating the plasma.

The optical measuring system in FIG. 2 further comprises a system for treating a photosensor that is also positioned within the vacuum chamber 40. The components of the system for treating the photosensor that have already been described in connection with FIG. 1 bear the same reference signs in FIG. 2. In the optical measuring system in FIG. 2, a holder for the photosensor is present within the camera 23.

The system for treating a photosensor that is located within the vacuum chamber 40 may be used, for example, before the first use of the optical measuring system or even after a certain operating time or after a certain number of measuring operations, to improve the quality of the photosensor 24. For this purpose, the EUV light source 25, the homogenizer 26, the collimator 27 and the stop device 30 are formed in the present case as a unit which can be displaced overall along the arrow 39 in front of the photosensor 24 or the camera 23, in order to make it possible to irradiate the photosensor 24 with the aid of the UV light source 25. The method for treating the photosensor 24 can thus be carried out, after the above-mentioned unit has been displaced, in the manner already described above in connection with FIG. 1.

In a variant of the method according to the invention, which is explained below with reference to FIG. 2, the extent of the dark current image aberration or the extent of the ghosting image aberration is determined in an alternative manner. To determine the dark current image aberration, the EUV light source 14 is switched off or blocked out in such a way that no light is incident on the photosensor 24. Electrical signals generated in the pixels are then detected despite darkness and forwarded to the evaluation unit in order to determine the dark current image aberration. The use of the stop 30 is therefore not necessary in this case.

Alternatively, for example, the mask 17 can be replaced by a predefined test structure 13 by use of a replacement unit 38. With the aid of the EUV radiation generated by the EUV light source 14, a first image of the test structure is then imaged onto the photosensor 24. The test structure 13 can then be displaced with the aid of the positioner 37 in order to record a second image different from the first at a short time interval of, for example, 100 ms. At least some pixels of the sensor 24 which have been illuminated by the EUV light source 14 prior to the displacement are not illuminated after the displacement. With the aid of the evaluation device, it is possible to determine, on the basis of the images recorded in succession, whether those pixels which were exposed in the first image and are unexposed in the second image generate an electrical signal in order to thus determine an extent of the ghosting image aberration in the manner already explained above in connection with FIG. 1.

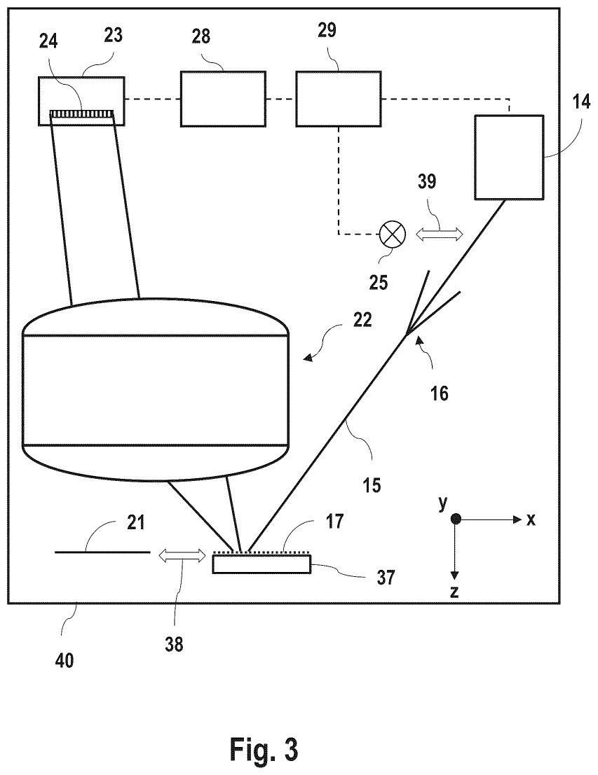

FIG. 3 shows a schematic illustration of an alternative embodiment of an optical measuring system according to the invention. The embodiment in FIG. 3 is substantially identical to the embodiment in FIG. 2, in which case the components already described above bear the same reference signs in FIG. 3. Only the differences from the embodiment shown in FIG. 2 shall be explained below.

The extent of the dark current image aberration and/or the ghosting image aberration can initially be determined in the manner already described above in connection with FIG. 2. After determining the image aberration, the UV light source 25 is displaced by use of a displacement device 39 such that the light from the UV light source 25 is directed via the illumination system 16 to the object plane. In addition, a mirror surface 21 can be introduced into the object plane with the aid of the displacement device 38.

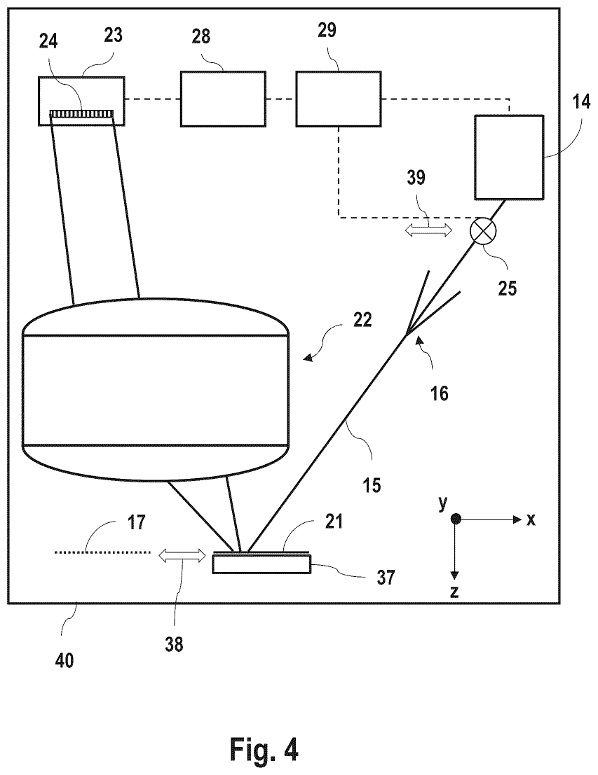

FIG. 4 shows the state of the optical measuring system in FIG. 3 after the UV light source 25 and the mirror surface 21 have been displaced. The UV light generated by the UV light source 25 is now directed via the illumination system 16 to the mirror surface 21, is reflected by the latter in the direction of the projection lens 22 and is imaged by the projection lens 22 onto the sensor surface of the photosensor 24. The UV light source 25 is controlled, according to the irradiation parameters determined previously on the basis of the extent of the image aberration, to irradiate the photosensor 24 with UV light. The UV radiation is incident on the entire surface of the sensor with a homogeneous intensity. The determination of the extent of the image aberration and the irradiation can then be repeated until the extent of the image aberration reaches an acceptable level.

In some examples, the evaluation unit 28 can be implemented by one or more computers, each computer can include one or more processor cores, and each processor core can include logic circuitry for processing data. Similarly, the control unit 29 can be implemented by one or more computers. In some examples, the evaluation unit 28 and the control unit 29 can be implemented by the same one or more computers. For example, a processor can include an arithmetic and logic unit (ALU), a control unit, and various registers. Each processor can include cache memory. Each processor can include a system-on-chip (SoC) that includes multiple processor cores, random access memory, graphics processing units, one or more controllers, and one or more communication modules. Each processor can include millions or billions of transistors.

The evaluation unit 28 and/or the control unit 29 can include one or more data processors for processing data, one or more storage devices for storing data, and/or one or more computer programs including instructions that when executed by the one or more computers cause the one or more computers to carry out the processes. The one or more computers can include one or more input devices, such as a keyboard, a mouse, a touchpad, and/or a voice command input module, and one or more output devices, such as a display, and/or an audio speaker.

In some implementations, the one or more computing devices can include digital electronic circuitry, computer hardware, firmware, software, or any combination of the above. The features related to processing of data can be implemented in a computer program product tangibly embodied in an information carrier, e.g., in a machine-readable storage device, for execution by a programmable processor; and method steps can be performed by a programmable processor executing a program of instructions to perform functions of the described implementations. Alternatively or in addition, the program instructions can be encoded on a propagated signal that is an artificially generated signal, e.g., a machine-generated electrical, optical, or electromagnetic signal, that is generated to encode information for transmission to suitable receiver apparatus for execution by a programmable processor.

A computer program can be written in any form of programming language, including compiled or interpreted languages, and it can be deployed in any form, including as a stand-alone program or as a module, component, subroutine, or other unit suitable for use in a computing environment.

For example, the one or more computers can be configured to be suitable for the execution of a computer program and can include, by way of example, both general and special purpose microprocessors, and any one or more processors of any kind of digital computer. Generally, a processor will receive instructions and data from a read-only storage area or a random access storage area or both. Elements of a computer system include one or more processors for executing instructions and one or more storage area devices for storing instructions and data. Generally, a computer system will also include, or be operatively coupled to receive data from, or transfer data to, or both, one or more machine-readable storage media, such as hard drives, magnetic disks, solid state drives, magneto-optical disks, or optical disks. Machine-readable storage media suitable for embodying computer program instructions and data include various forms of non-volatile storage area, including by way of example, semiconductor storage devices, e.g., EPROM, EEPROM, flash storage devices, and solid state drives; magnetic disks, e.g., internal hard disks or removable disks; magneto-optical disks; and CD-ROM, DVD-ROM, and/or Blu-ray discs.

In some implementations, the processes described above can be implemented using software for execution on one or more mobile computing devices, one or more local computing devices, and/or one or more remote computing devices (which can be, e.g., cloud computing devices). For instance, the software forms procedures in one or more computer programs that execute on one or more programmed or programmable computer systems, either in the mobile computing devices, local computing devices, or remote computing systems (which may be of various architectures such as distributed, client/server, grid, or cloud), each including at least one processor, at least one data storage system (including volatile and non-volatile memory and/or storage elements), at least one wired or wireless input device or port, and at least one wired or wireless output device or port.

In some implementations, the software may be provided on a medium, such as CD-ROM, DVD-ROM, Blu-ray disc, a solid state drive, or a hard drive, readable by a general or special purpose programmable computer or delivered (encoded in a propagated signal) over a network to the computer where it is executed. The functions can be performed on a special purpose computer, or using special-purpose hardware, such as coprocessors. The software can be implemented in a distributed manner in which different parts of the computation specified by the software are performed by different computers. Each such computer program is preferably stored on or downloaded to a storage media or device (e.g., solid state memory or media, or magnetic or optical media) readable by a general or special purpose programmable computer, for configuring and operating the computer when the storage media or device is read by the computer system to perform the procedures described herein. The inventive system can also be considered to be implemented as a computer-readable storage medium, configured with a computer program, where the storage medium so configured causes a computer system to operate in a specific and predefined manner to perform the functions described herein.

A number of embodiments of the invention have been described. Nevertheless, it will be understood that various modifications may be made without departing from the spirit and scope of the invention. For example, the wavelength of the UV light can be different from what is described above.

What is claimed is:

1. A method for treating a photosensor, in particular for use in an optical measuring system for semiconductor lithography, wherein the photosensor has a sensor surface having a plurality of photosensitive pixels which are designed to convert light into an electrical signal using the internal photoelectric effect, comprising the following steps:
determining an extent of an image aberration caused by a dark current effect and/or a ghosting effect;
irradiating the sensor surface of the photosensor with UV light; and
repeating the determination of the extent of the image aberration and the irradiation of the sensor surface until the determined extent of the image aberration falls below a specified level.

2. The method of claim 1, in which an irradiation parameter used for the irradiation is selected on the basis of the extent of the dark current effect and/or the ghosting effect, wherein the at least one irradiation parameter is preferably selected from the group comprising irradiation duration, irradiation intensity and irradiation wavelength.

3. The method of claim 1, in which a wavelength of the UV light is in the range between 150 nm and 350 nm.

4. The method of claim 1, in which the extent of the image aberration is determined by determining a dark current effect of the photosensor.

5. The method of claim 1, in which the determination of the extent of the image aberration comprises the following steps:
successively detecting a first light distribution and a second light distribution different from the first by use of the photosensor; and
determining an effect of detecting the first light distribution on an image obtained by detecting the second light distribution.

6. The method of claim 1, in which the sensor surface is irradiated with UV light in such a way that a difference between radiation intensities which are incident on different sections of the photosensor is less than 10% of a maximum radiation intensity.

7. The method of claim 1, in which a UV light source is used to determine the extent of the image aberration, wherein the irradiation is also carried out with the aid of the UV light source.

8. The method of claim 1, in which a first light source is used to determine the extent of the image aberration, wherein the sensor surface is irradiated with UV light with the aid of a second light source different from the first.

9. The method of claim 1, wherein the method is carried out within a mask inspection apparatus, wherein the mask inspection apparatus comprises an illumination source, an illumination optical unit for illuminating an object plane and a projection optical unit for imaging the object plane onto the photosensor, wherein a mask to be examined can be positioned in the object plane.

10. The method of claim 9, wherein a mirror surface is positioned in the object plane, wherein the illumination source or a UV light source different from the illumination source is used to irradiate the sensor surface via the illumination optical unit, the mirror surface and the projection optical unit.

11. The method of claim 1, in which the photosensor is a CCD sensor or a CMOS sensor.

12. The method of claim 1, which is carried out for treating a first photosensor in order to determine at least one irradiation parameter, with which the extent of the image aberration is reduced below the specified level, wherein the irradiation parameter is used to irradiate the sensor surface of a second photosensor different from the first photosensor.

13. A system for treating a photosensor, in particular for use in an optical measuring system for semiconductor lithography, wherein the photosensor has a sensor surface having a plurality of photosensitive pixels which are designed to convert light into an electrical signal using the internal photoelectric effect, comprising: a holder for the photosensor; a UV light source for illuminating a sensor surface of the photosensor held by the holder; an evaluation unit which is designed to receive sensor data from the photosensor and to determine an extent of an image aberration of the photosensor that is caused by a dark current effect and/or by a ghosting effect; a control unit which is configured to interact with the evaluation unit and the UV light source in such a way that the method of claim 1 is carried out.

14. An optical measuring system for measuring an optical property of an object, in particular for measuring a quality of a lithographic mask, wherein the object can be arranged in an object plane, comprising an illumination source; a photosensor having a sensor surface having a plurality of photosensitive pixels which are designed to convert light into an electrical signal using the internal photoelectric effect; an illumination optical unit which is designed to transform light from the illumination source into an illumination beam path for illuminating the object plane; a projection optical unit for imaging the object plane onto the sensor surface; a UV light source for irradiating the sensor surface with UV light; an evaluation unit which is designed to receive sensor data from the photosensor and to determine an extent of an image aberration of the photosensor that is caused by a dark current effect and/or by a ghosting effect; and a control unit which is configured to receive information about the extent of the image aberration from the evaluation unit and to deliver control signals to the UV light source, as well as to adapt the control signals on the basis of the information about the extent of the image aberration.

15. The optical measuring system of claim 14, which is configured to image either light from the UV light source or light from the illumination source onto the photosensor via the illumination optical unit, an object located in the object plane and the projection optical unit.

16. The optical measuring system of claim 14, in which the control unit is configured to select an irradiation parameter used for the irradiation on the basis of the extent of the dark current effect and/or the ghosting effect, wherein the at least one irradiation parameter is selected from the group comprising irradiation duration, irradiation intensity and irradiation wavelength.

17. The optical measuring system of claim 14, in which the UV light source is configured to produce UV light having a wavelength in a range from 150 nm to 350 nm.

18. The optical measuring system of claim 14, in which the evaluation unit is configured to determine the extent of the image aberration by determining a dark current effect of the photosensor.

19. The optical measuring system of claim 14, in which the evaluation unit is configured to determine the extent of the image aberration using the following steps:
successively detecting a first light distribution and a second light distribution different from the first by use of the photosensor; and
determining an effect of detecting the first light distribution on an image obtained by detecting the second light distribution.

20. The system of claim 13, in which the control unit is configured to select an irradiation parameter used for the irradiation on the basis of the extent of the dark current effect and/or the ghosting effect, wherein the at least one irradiation parameter is selected from the group comprising irradiation duration, irradiation intensity and irradiation wavelength.
